(19) United States
(12) Patent Application Publication
(10) Pub. No.: US 2026/0013155 A1
(43) Pub. Date: Jan. 8, 2026

(54) SEMICONDUCTOR DEVICE

(71) Applicant: Vanguard International Semiconductor Corporation, Hsinchu (TW)

(72) Inventors: Yu-Hao Ho, Hsinchu City (TW); Cheng-Tsung Wu, Hsinchu County (TW); Fu-Chun Tseng, Taipei City (TW)

(73) Assignee: Vanguard International Semiconductor Corporation, Hsinchu (TW)

(21) Appl. No.: 18/764,200

(22) Filed: Jul. 4, 2024

(51) Int. Cl. H01L 29/872; H01L 29/06; H01L 29/66

(52) U.S. Cl. CPC H10D 8/60; H10D 8/051; H10D 62/115; H10D 62/126

(57) ABSTRACT

A semiconductor device includes a first well region having a first conductivity type and disposed in a substrate. A first doped region having a second conductivity type is disposed in the first well region. The first doped region includes a first portion and a second portion laterally separated from each other. A second doped region having the first conductivity type is disposed between and not in direct contact with the first portion and the second portion. A third doped region having the first conductivity type is disposed in the first well region and surrounds the first doped region and the second doped region. An anode electrode is disposed above the substrate and electrically connected to the second doped region. A cathode electrode is disposed above the substrate and electrically connected to the third doped region.

### BACKGROUND OF THE INVENTION

### 1. Field of the Invention

The present disclosure relates generally to semiconductor devices, and more particularly to semiconductor devices for Schottky barrier diodes.

### 2. Description of the Prior Art

A Schottky barrier diode (SBD) is a semiconductor device using Schottky barrier characteristics of a metal-semiconductor junction. When the SBD is forward biased, a positive voltage is applied to the anode and a negative voltage is applied to the cathode, thereby conducting the carriers in the SBD. When the SBD is reverse biased, a negative voltage is applied to the anode and a positive voltage is applied to the cathode, so that the carriers are not conducted easily in the SBD. Therefore, the SBD has a rectifying effect of one-way conduction. Since the Schottky barrier is lower than the junction barrier of p-type and n-type semiconductors, compared with PN junction diodes, Schottky barrier diodes have advantages of low turn-on voltage, low voltage drop under forward bias and fast switching speed. The Schottky barrier diodes are suitable for applications with low power consumption, high current and high switching speed, and have been widely used in various electronic devices. However, considering various requirements for application and the characteristics of diodes, the current Schottky barrier diodes still cannot fully satisfy the requirements in all aspects.

### SUMMARY OF THE INVENTION

In view of this, the present disclosure provides a semiconductor device for a Schottky barrier diode (SBD). In the semiconductor device, an n-type doped region (or referred to as an n-type well region) is added at an anode end, thereby increasing the capability of driving current of the SBD. Moreover, the forward current of the SBD is significantly enhanced without affecting the electrical breakdown voltage, thereby improving the overall performances of the semiconductor device.

According to an embodiment of the present disclosure, a semiconductor device is provided and includes a substrate, a first well region, a first doped region, a second doped region, a third doped region, an anode electrode and a cathode electrode. The first well region has a first conductivity type and is disposed in the substrate. The first doped region has a second conductivity type opposite to the first conductivity type and is disposed in the first well region. The first doped region includes a first portion and a second portion, which are laterally separated from each other. The second doped region having the first conductivity type is disposed between the first portion and the second portion, and not in direct contact with the first portion and the second portion of the first doped region. The third doped region having the first conductivity type is disposed in the first well region, and surrounds the first doped region and the second doped region. The anode electrode is disposed above the substrate and electrically connected to the second doped region. The cathode electrode is disposed above the substrate and electrically connected to the third doped region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic top view of a semiconductor device according to an embodiment of the present disclosure.

FIG. 2 is a schematic cross-sectional view of a semiconductor device according to an embodiment of the present disclosure, which is taken along a cross-sectional line A-A in FIG. 1.

FIG. 3 is a schematic top view of a semiconductor device according to another embodiment of the present disclosure.

FIG. 4 is a schematic top view of a semiconductor device according to further another embodiment of the present disclosure.

FIG. 5, FIG. 6, FIG. 7 and FIG. 8 are schematic cross-sectional views of some stages of a method of fabricating a semiconductor device according to an embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “under,” “lower,” “over,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as “below” and/or “beneath” other elements or features would then be oriented “above” and/or “over” the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first,” “second,” and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that can vary as desired.

Furthermore, as disclosed herein, the terms “coupled to” and “electrically connected to” include any directly and indirectly electrical connecting means. Therefore, if it is described in this document that a first component is coupled or electrically connected to a second component, it means that the first component may be directly connected to the second component, or may be indirectly connected to the second component through other components or other connecting means.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

The present disclosure relates to a semiconductor device for a Schottky barrier diode (SBD). In the semiconductor device, an n-type doped region (or referred to as an n-type well region) is added at an anode end without additional photo-masks and process steps to effectively increase the drive-in current of the SBD, thereby enhancing the forward current (IF) of the SBD. Moreover, the breakdown voltage (BV) of the SBD is kept. Therefore, the overall electrical performances of the semiconductor device are greatly improved.

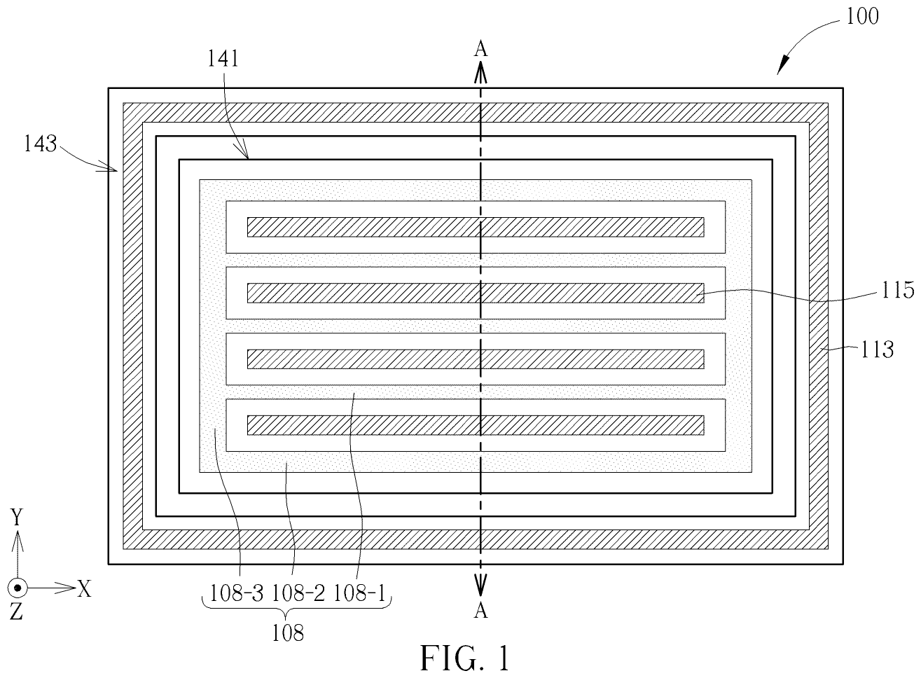

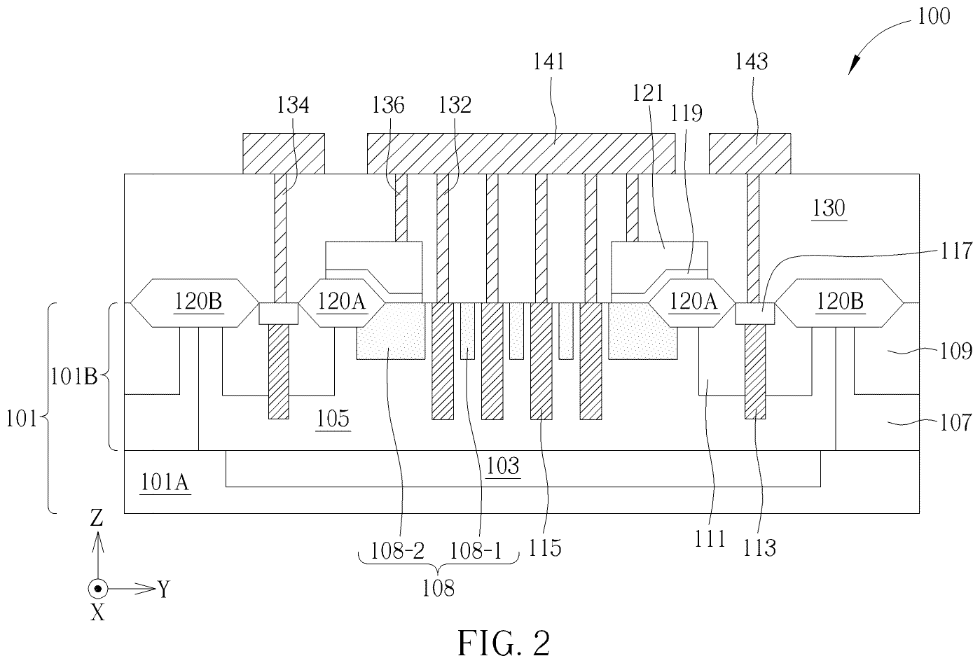

FIG. 1 is a schematic top view of a semiconductor device 100 according to an embodiment of the present disclosure. In order to make the figure concise and easy to understand, some features of the semiconductor device are not shown in FIG. 1. The other features of the semiconductor device may refer to FIG. 2, which shows a schematic cross-sectional view of the semiconductor device 100. As shown in FIG. 1, the semiconductor device 100 includes an anode electrode 141 and a cathode electrode 143. In one embodiment, when viewed from a top view, the anode electrode 141 is, for example, a rectangular block, and the cathode electrode 143 is, for example, a rectangular annular block surrounding the anode electrode 141. In addition, a first doped region 108 and a second doped region 115 are disposed directly below the anode electrode 141. The second doped region 115 has a first conductivity type, for example, an n-type doped region (or referred to as an n-type well region). The first doped region 108 has a second conductivity type opposite to the first conductivity type, for example, a p-type doped region (or referred to as a p-type body region). The first doped region 108 includes a first portion 108-1 and a second portion 108-2, which are laterally separated from each other in the Y-axis direction. The first portion 108-1 is located in an inner region and the second portion 108-2 is located in an outer region of the first doped region 108. The second doped region 115 is disposed between the first portion 108-1 and the second portion 108-2 of the first doped region 108, and not in direct contact with the first portion 108-1 and the second portion 108-2. The long axes of the first portion 108-1 and the second portion 108-2 of the first doped region 108 and the long axis of the second doped region 115 are all extended along the X-axis direction. In addition, the first doped region 108 further includes a third portion 108-3 that is connected to two ends of both the first portion 108-1 and the second portion 108-2. The second doped region 115 is not in direct contact with the third portion 108-3. The long axis of the third portion 108-3 is extended along the Y-axis direction. In this embodiment, when viewed from a top view, the second portion 108-2 and the third portion 108-3 of the first doped region 108 construct a rectangular annular block. The first portion 108-1 of the first doped region 108 and the second doped region 115 are multiple elongated blocks parallel to each other. Furthermore, a third doped region 113 is disposed directly below the cathode electrode 143. The third doped region 113 has the first conductivity type, for example, an n-type doped region (or referred to as an n-type well region). The third doped region 113 surrounds the first doped region 108 and the second doped region 115. In this embodiment, when viewed from a top view, the third doped region 113 is a rectangular annular block.

FIG. 2 is a schematic cross-sectional view of a semiconductor device 100 according to an embodiment of the present disclosure, which is taken along a cross-sectional line A-A in FIG. 1. As shown in FIG. 2, the semiconductor device 100 includes a substrate 101 having the second conductivity type, for example, a p-type semiconductor substrate. The substrate 101 may be composed of a base substrate 101A and an epitaxial layer 101B. For example, a p-type epitaxial layer 101B is grown on a p-type base substrate 101A. The composition of the base substrate 101A may be the same as or different from the composition of the epitaxial layer 101B. In some embodiments, the compositions of the base substrate 101A and the epitaxial layer 101B may be selected from a group consisting of silicon (Si), germanium (Ge), silicon carbide (SiC), silicon germanium (SiGe) and group III-V compound semiconductors, such as gallium nitride (GaN), gallium arsenide (GaAs), aluminum nitride (AlN), aluminum gallium nitride (AlGaN), indium aluminum gallium nitride (InAlGaN), indium gallium nitride (InGaN), aluminum gallium arsenide (AlGaAs), indium gallium arsenide (InGaAs), other similar compound semiconductors or a combination thereof. In other embodiments, the substrate 101 may be an n-type semiconductor substrate or a semiconductor-on-insulator (SOI) substrate.

Still: referring to FIG. 2, in one embodiment, the semiconductor device 100 may include a buried layer 103 and a first well region 105 disposed in the substrate 101. The buried layer 103 has the first conductivity type, for example, an n-type buried layer (NBL). The first well region 105 has the first conductivity type, for example, an n-type well region. The buried layer 103 is disposed in the base substrate 101A, and the first well region 105 is disposed in the epitaxial layer 101B. The buried layer 103 is located directly below the first well region 105, and the buried layer 103 is in direct contact with the bottom surface of the first well region 105. In addition, the semiconductor device 100 includes a first doped region 108 having the second conductivity type, for example, a p-type doped region (or referred to as a p-type body region). The first doped region 108 is disposed in the first well region 105 and close to the top surface of the first well region 105. In one embodiment, the first doped region 108 includes a first portion 108-1 and a second portion 108-2, which are laterally separated from each other, and a third portion 108-3 as shown in FIG. 1. The doping concentrations of the first portion 108-1, the second portion 108-2 and the third portion 108-3 are the same, and the bottom surfaces of the aforementioned portions of the first doped region 108 are at the same level in the depth.

In addition, the semiconductor device 100 includes a second doped region 115 having the first conductivity type, for example, an n-type doped region (or referred to as an n-type well region). The second doped region 115 is disposed in the first well region 105. The doping concentration of the second doped region 115 is higher than the doping concentration of the first well region 105. The second doped region 115 is disposed between the first portion 108-1 and the second portion 108-2 of the first doped region 108, and the second doped region 115 is not in direct contact with the first portion 108-1, the second portion 108-2 and the third portion 108-3 (shown in FIG. 1) of the first doped region 108. Moreover, the top surface of the second doped region 115 and the top surface of the first doped region 108 are both close to the top surface of the first well region 105. The bottom surface of the second doped region 115 is lower than the bottom surface of the first doped region 108. In addition, the second doped region 115 may be electrically connected to the anode electrode 141 through multiple contact plugs 132 passing through an interlayer dielectric (ILD) layer 130. According to some embodiments of the present disclosure, the n-type second doped region 115 disposed at the anode end can reduce the contact resistance at the anode end, thereby effectively increasing the forward current (IF) of the SBD.

Still referring to FIG. 2, the semiconductor device 100 further includes a third doped region 113 disposed in the first well region 105. The third doped region 113 has the first conductivity type, for example, an n-type doped region (or referred to as an n-type well region). The third doped region 113 surrounds the first doped region 108 and the second doped region 115. The third doped region 113 may be electrically connected to the cathode electrode 143 through multiple contact plugs 134 passing through the ILD layer 130. According to some embodiments of the present disclosure, the third doped region 113 and the second doped region 115 may be formed simultaneously by using the same photo-mask and the same ion implantation process. Therefore, the third doped region 113 and the second doped region 115 may have the same doping concentration, and the bottom surface of the third doped region 113 may be level with the bottom surface of the second doped region 115. According to some embodiments of the present disclosure, the effects of increasing the forward current and maintaining the breakdown voltage of the SBD are achieved by forming the second doped region 115, and forming the second doped region 115 at the anode end does not require additional photo-masks and process steps.

In addition, the anode electrode 141 and the cathode electrode 143 are both disposed above the substrate 101 and located on the top surface of the ILD layer 130. The compositions of the anode electrode 141, the cathode electrode 143 and the multiple contact plugs 132 and 134 are metals that can produce Schottky contact, such as gold (Au), silver (Ag), platinum (Pt), tungsten (W), titanium (Ti), aluminum (Al), molybdenum (Mo), nickel (Ni), cobalt (Co) or a combination thereof.

Still referring to FIG. 2, the semiconductor device 100 further includes a fourth doped region 111 disposed in the first well region 105. The fourth doped region 111 has the first conductivity type, for example, an n-type double diffusion (NDD) region. The third doped region 113 is located in the fourth doped region 111, and the bottom surface of the third doped region 113 is lower than the bottom surface of the fourth doped region 111. In addition, the fourth doped region 111 is laterally separated from the first doped region 108, and the bottom surface of the fourth doped region 111 is lower than the bottom surface of the first doped region 108. The semiconductor device 100 further includes a heavily doped region 117 disposed in the fourth doped region 111. The heavily doped region 117 has the first conductivity type, for example, an n-type heavily doped (N⁺) region. The heavily doped region 117 is located directly above the third doped region 113, and the third doped region 113 is in direct contact with the heavily doped region 117. The heavily doped region 117 and the third doped region 113 may be electrically connected to the cathode electrode 143 through the multiple contact plugs 134 passing through the ILD layer 130. In addition, the doping concentration of the fourth doped region 111 is higher than the doping concentration of the first well region 105. The doping concentration of the third doped region 113 is higher than the doping concentration of the fourth doped region 111, and the doping concentration of the heavily doped region 117 is higher than the doping concentration of the third doped region 113. The heavily doped region 117 and the third doped region 113 can reduce the contact resistance at the cathode end, thereby facilitating current flowing from the high voltage end of the cathode to the low voltage end of the anode.

In addition, the semiconductor device 100 includes a first isolation structure 120A disposed in the first well region 105 and located between the first doped region 108 and the fourth doped region 111 to electrically isolate the anode end and the cathode end of the semiconductor device 100. An electrically conductive structure 121 is disposed on the first doped region 108 and laterally extends onto the first isolation structure 120A. The electrically conductive structure 121 may be electrically connected to the anode electrode 141 through multiple contact plugs 136 that pass through the ILD layer 130. A dielectric layer 119 is disposed between the electrically conductive structure 121 and the first doped region 108, and also between the electrically conductive structure 121 and the first isolation structure 120A. When the SBD is reverse biased, the electrically conductive structure 121 disposed on the first doped region 108 and electrically connected to the anode electrode 141 can provide an electric field dispersion effect, thereby enhancing the breakdown voltage of the semiconductor device 100 under reverse bias.

As shown in FIG. 2, the semiconductor device 100 further includes a second well region 107 disposed in the epitaxial layer 101B of the substrate 101. The second well region 107 has the second conductivity type, for example, a p-type high voltage well region (HVPW). The second well region 107 surrounds and abuts the first well region 105. In some embodiments, the bottom surface of the second well region 107 is level with the bottom surface of the first well region 105, i.e., the bottom surfaces of the second well region 107 and the first well region 105 are at the same level in depth, but not limited thereto. In addition, a third well region 109 is disposed in the second well region 107. The third well region 109 has the second conductivity type, for example, a p-type low voltage well region (LVPW). The doping concentration of the third well region 109 is higher than that of the second well region 107. The third well region 109 may be electrically coupled to a bulk potential through other conductive lines (not shown) on the ILD layer 130 and other contact plugs (not shown) in the ILD layer 130. Moreover, the second well region 107 and the third well region 109 may be used to electrically isolate the semiconductor device 100 from other adjacent electronic components. The semiconductor device 100 further includes a second isolation structure 120B disposed between the first well region 105 and the second well region 107. The second isolation structure 120B may be used to electrically isolate the cathode end and the bulk end of the semiconductor device 100. In some embodiments, the first isolation structure 120A and the second isolation structure 120B are, for example, field oxide (FOX) structures or shallow trench isolation (STI) structures.

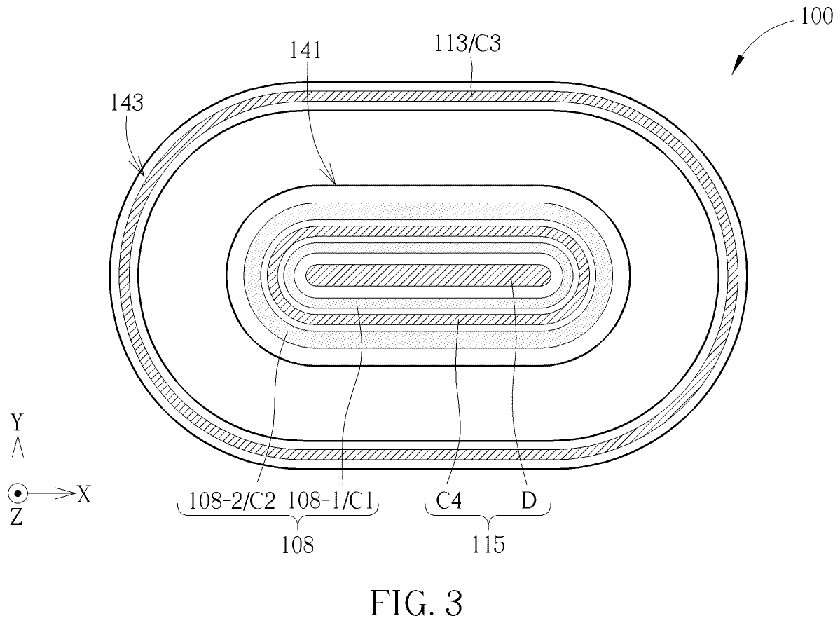

FIG. 3 is a schematic top view of a semiconductor device 100 according to another embodiment of the present disclosure. In order to make the figure concise and easy to understand, some features of the semiconductor device are not shown in FIG. 3. The other features of the semiconductor device may refer to FIG. 2, which shows a schematic cross-sectional view of the semiconductor device 100. In the semiconductor device 100 of FIG. 3, when viewed from a top view, a first doped region 108 and a second doped region 115 are disposed directly below an anode electrode 141, and a third doped region 113 is disposed directly below a cathode electrode 143. The first doped region 108 includes a first portion 108-1 and a second portion 108-2, which are laterally separated from each other. The planar layout of the first portion 108-1 and the second portions 108-2 of the first doped region 108 and the third doped region 113 includes a first annular region C1, a second annular region C2 and a third annular region C3 arranged in a racetrack shape from inside to outside in sequence. The second doped region 115 includes a fourth annular region C4 and a block D. The fourth annular region C4 is located between the first annular region C1 and the second annular region C2, and the block D is surrounded by the first annular region C1. The anode electrode 141 may be a block that conforms to the outer contour of the second annular region C2 and completely covers the first doped region 108 and the second doped region 115. The cathode electrode 143 may be an annular block that conforms to the inner and outer contours of the third annular region 113C and completely covers the third doped region 113. FIG. 3 illustrates an example of the planar layout of the first doped region 108, the second doped region 115 and the third doped region 113 arranged in a racetrack shape, and the corresponding planar layout of the anode electrode 141 and the cathode electrode 143. The number of the annular regions of the first doped region 108 is not limited to two annular regions as shown in FIG. 3. Other numbers of the annular regions and other racetrack-shaped planar layouts may be used according to the requirements of the semiconductor devices.

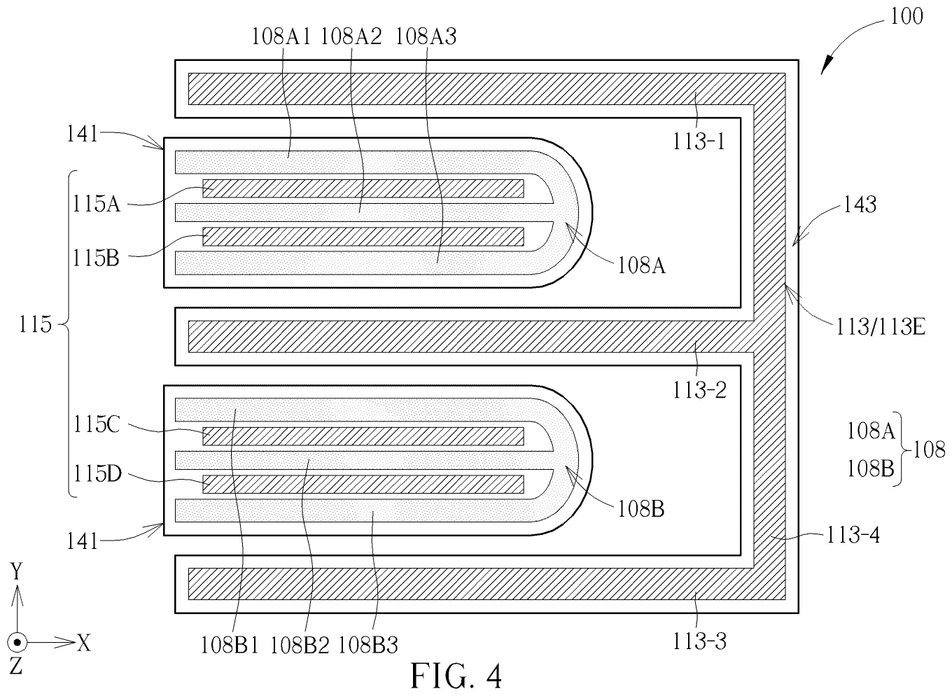

FIG. 4 is a schematic top view of a semiconductor device 100 according to further another embodiment of the present disclosure. In order to make the figure concise and easy to understand, some features of the semiconductor device are not shown in FIG. 4. The other features of the semiconductor device may refer to FIG. 2, which shows a schematic cross-sectional view of the semiconductor device 100. In the semiconductor device 100 of FIG. 4, when viewed from a top view, a first doped region 108 and a second doped region 115 are disposed directly below an anode electrode 141, and a third doped region 113 is disposed directly below a cathode electrode 143. In this embodiment, the third doped region 113 includes a main comb-shaped region 113E, and the first doped region 108 includes a first sub-comb-shaped region 108A and a second sub-comb-shaped region 108B. In addition, the main comb-shaped region 113E includes a first strip portion 113-1, a second strip portion 113-2 and a third strip portion 113-3, which are laterally separated in the Y-axis direction. The long axes of these strip portions of the main comb-shaped region 113E are extended along the X-axis direction. The main comb-shaped region 113E further includes a fourth strip portion 113-4, which is connected to the same side ends of the first strip portion 113-1, the second strip portion 113-2 and the third strip portion 113-3.

Furthermore, the first sub-comb-shaped region 108A of the first doped region 108 is located between the first strip portion 113-1 and the second strip portion 113-2, and the second sub-comb-shaped region 108B is located between the second strip portion 113-2 and the third strip portion 113-3 of the main comb-shaped region 113E. The first sub-comb-shaped region 108A includes a first sub-strip portion 108A1, a second sub-strip portion 108A2 and a third sub-strip portion 108A3, which are laterally separated in the Y-axis direction. The long axes of these sub-strip portions of the first sub-comb-shaped region 108A are extended along the X-axis direction, and the same side ends of these sub-strip portions are connected together. Similarly, the second sub-comb-shaped region 108B includes a fourth sub-strip portion 108B1, a fifth sub-strip portion 108B2 and a sixth sub-strip portion 108B3, which are laterally separated in the Y-axis direction. The long axes of these sub-strip portions of the second sub-comb-shaped region 108B are extended along the X-axis direction, and the same side ends of these sub-strip portions are connected together.

Moreover, the second doped region 115 includes a first elongated block 115A, a second elongated block 115B, a third elongated block 115C and a fourth elongated block 115D, which are laterally separated in the Y-axis direction. The long axes of these elongated blocks of the second doped region 115 are extended along the X-axis direction. The first elongated block 115A is located between the first sub-strip portion 108A1 and the second sub-strip portion 108A2 of the first sub-comb-shaped region 108A. The second elongated block 115B is located between the second sub-strip portion 108A2 and the third sub-strip portion 108A3 of the first sub-comb-shaped region 108A. The third elongated block 115C is located between the fourth sub-strip portion 108B1 and the fifth sub-strip portion 108B2 of the second sub-comb-shaped region 108B. The fourth elongated block 115D is located between the fifth sub-strip portion 108B2 and the sixth sub-strip portion 108B3 of the second sub-comb-shaped region 108B.

As shown in FIG. 4, the first strip portion 113-1, the second strip portion 113-2 and the third strip portion 113-3 of the main comb-shaped region 113E, the first sub-strip portion 108A1, the second sub-strip portion 108A2 and the third sub-strip portion 108A3 of the first sub-comb-shaped region 108A, the fourth sub-strip portion 108B1, the fifth sub-strip portion 108B2 and the sixth sub-strip portion 108B3 of the second sub-comb-shaped region 108B, and the first elongated block 115A, the second elongated block 115B, the third elongated block 115C and the fourth elongated block 115D of the second doped region 115 are all laterally separated from each other in the Y-axis direction, and their long axes are parallel to each other. The anode electrode 141 may be a block that conforms to the outer contours of the first sub-comb-shaped region 108A and the second sub-comb-shaped region 108B, and completely covers the first doped region 108 and the second doped region 115. The cathode electrode 143 may be a comb-shaped block that conforms to the inner and outer contours of the main comb-shaped region 113E and completely covers the third doped region 113.

FIG. 4 illustrates an example of the planar layout of the first doped region 108 and the third doped region 113 arranged in a comb shape, and the corresponding planar layout of the second doped region 115, the anode electrode 141 and the cathode electrode 143. The number of the strip portions of the third doped region 113 is not limited to three strip portions as shown in FIG. 4, and the number of sub-strip portions of the first doped region 108 is not limited to three sub-strip portions as shown in FIG. 4. Other numbers of the strip portions and the sub-strip portions, and other corresponding numbers of the sub-comb-shaped regions and the elongated blocks of the second doped region 115 may be used according to the requirements of the semiconductor devices.

According to some embodiments of the present disclosure, the second doped region 115 with a higher doping concentration than the first well region 105 is disposed at the anode end, which can reduce the on-state resistance, thereby increasing the capability of driving current of the SBD. Compared with a SBD of a comparative example without the second doped region 115, the forward current (IF) of the SBD of the semiconductor device 100 of the present disclosure is greatly increased about 3 times. Moreover, in the embodiments of the present disclosure, the second doped region 115 is not in direct contact with the first doped region 108, and the first well region 105 with a lower doping concentration is disposed between the second doped region 115 and the first doped region 108. Accordingly, a depletion region is formed between the n-type first well region 105 and the p-type first doped region 108, which produces a pinch effect on the leakage current in the off state, thereby maintaining the breakdown voltage (BV) of the SBD under reverse bias.

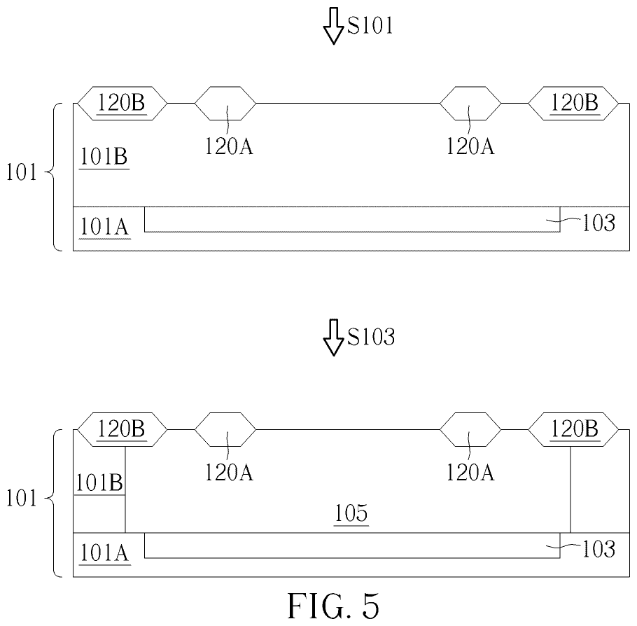

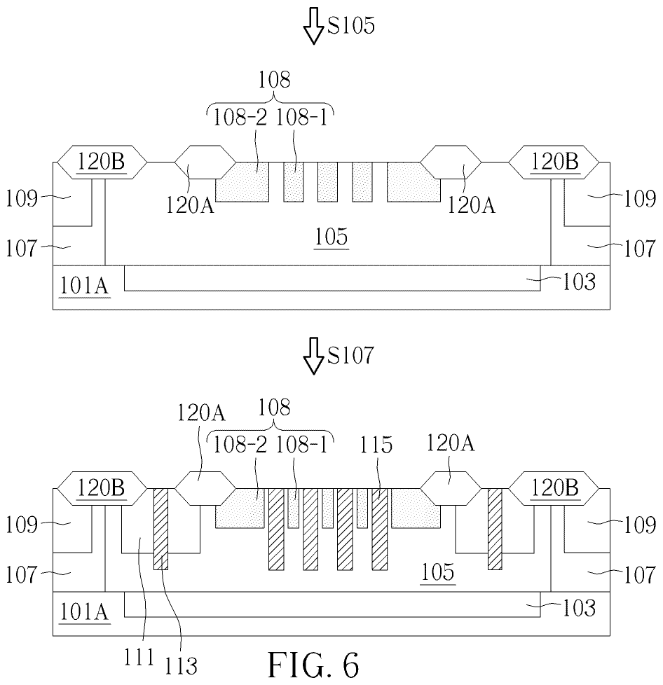

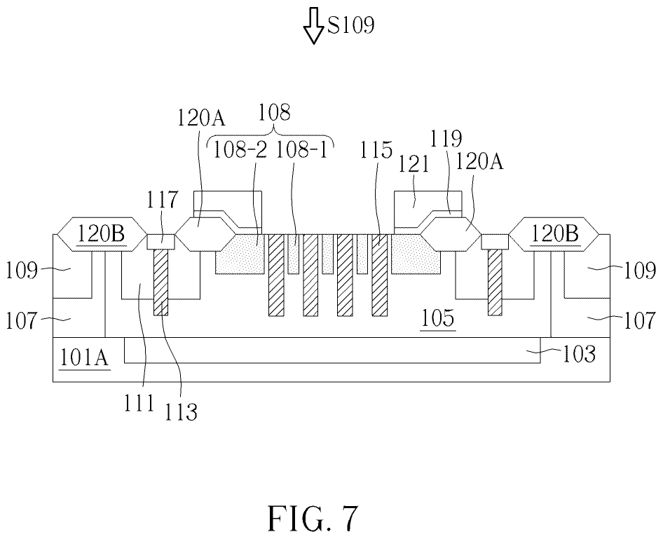

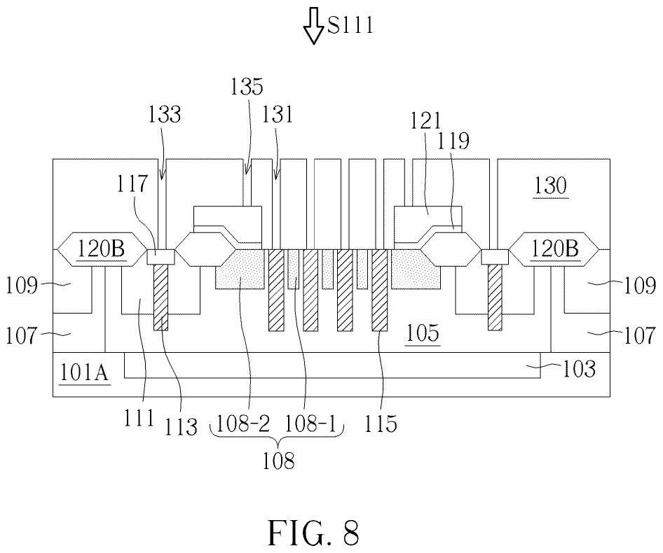

FIG. 5, FIG. 6, FIG. 7 and FIG. 8 are schematic cross-sectional views of some stages of a method of fabricating a semiconductor device 100 according to an embodiment of the present disclosure. Referring to FIG. 5, in step S101, firstly, a base substrate 101A, such as a silicon (Si) wafer, a silicon carbide (Sic) wafer or a p-type semiconductor substrate, is provided. Next, a buried layer 103 such as an n-type buried layer (NBL) is formed in the base substrate 101A by using a patterned mask such as a patterned photoresist and an ion implantation process. Then, an epitaxial layer 101B is formed on the base substrate 101A by an epitaxial growth process, so that the buried layer 103 is embedded in the base substrate 101A and the epitaxial layer 101B. The epitaxial layer 101B is, for example, a silicon (Si) epitaxial layer, a silicon carbide (SiC) epitaxial layer or a p-type semiconductor epitaxial layer. The base substrate 101A and the epitaxial layer 101B together construct a substrate 101.

Afterwards, a first isolation structure 120A and a second isolation structure 120B are formed in the epitaxial layer 101B of the substrate 101. The second isolation structure 120B surrounds the first isolation structure 120A. In one embodiment, both the first isolation structure 120A and the second isolation structure 120B are field oxide (FOX) structures and may be simultaneously formed on the epitaxial layer 101B by using a patterned mask and a thermal oxidation process. In another embodiment, the first isolation structure 120A and the second isolation structure 120B are shallow trench isolation (STI) structures. Firstly, multiple shallow trenches are formed in the epitaxial layer 101B by an etching process, and then these shallow trenches are filled up with a dielectric material. Next, a chemical mechanical planarization (CMP) process is performed to simultaneously form the aforementioned isolation structures.

Still referring to FIG. 5, in step S103, a first well region 105 such as an n-type well region is formed in the epitaxial layer 101B by using a patterned mask such as a patterned photoresist and an ion implantation process. The first well region 105 is located directly above and in direct contact with the buried layer 103. In some embodiments, the width of the first well region 105 may be greater than or approximately equal to the width of the buried layer 103. Furthermore, the second isolation structure 120B surrounds the first well region 105, and the first isolation structure 120A is located in the first well region 105.

Next, referring to FIG. 6, in step S105, a first doped region 108 such as a p-type doped region is formed in the first well region 105 by using a patterned mask such as a patterned photoresist and an ion implantation process. The first doped region 108 is close to the top surface of the first well region 105, and the first isolation structure 120A surrounds the first doped region 108. The first doped region 108 includes a first portion 108-1 and a second portion 108-2, which are laterally separated from each other. The first isolation structure 120A may be in direct contact with the peripheral portion of the first doped region 108, for example, the second portion 108-2 and the third portion 108-3 as shown in FIG. 1. In some embodiments, the doping concentration of the first doped region 108 is, for example, about 1E13 atoms/cm² to about 3E14 atoms/cm². In addition, the various planar layouts of the first doped region 108 may refer to the aforementioned FIG. 1, FIG. 3 and FIG. 4.

Thereafter, a second well region 107 such as a p-type high voltage well region (HVPW) is formed in the epitaxial layer 101B of the substrate 101 by using another patterned mask such as a patterned photoresist and an ion implantation process. The second well region 107 surrounds and abuts the side surfaces of the first well region 105. In one embodiment, the bottom surface of the second well region 107 is level with the bottom surface of the first well region 105. Next, a third well region 109 such as a p-type low voltage well region (LVPW) is formed in the second well region 107 by using another patterned mask and an ion implantation process. The doping concentration of the third well region 109 is higher than the doping concentration of the second well region 107. In some embodiments, the doping concentration of the second well region 107 is, for example, about 5E12 atoms/cm² to about 5E13 atoms/cm², and the doping concentration of the third well region 109 is, for example, about 1E13 atoms/cm² to about 3E14 atoms/cm². In addition, the second isolation structure 120B is located between the first well region 105 and the second well region 107.

Still referring to FIG. 6, in step S107, a fourth doped region 111 such as an n-type double diffusion region (NDD) is formed in the first well region 105 by using a patterned mask such as a patterned photoresist and an ion implantation process. The doping concentration of the fourth doped region 111 is higher than the doping concentration of the first well region 105. In some embodiments, the doping concentration of the fourth doped region 111 is, for example, about 5E13 atoms/cm² to about 5E14 atoms/cm², and the doping concentration of the first well region 105 is, for example, about 1E12 atoms/cm² to about 3E13 atoms/cm².

Then, a second doped region 115 is formed in the first well region 105 and a third doped region 113 is formed in the fourth doped region 111 simultaneously by using the same patterned mask such as a patterned photoresist and the same ion implantation process. Both the second doped region 115 and the third doped region 113 are, for example, n-type doped regions (or referred to as n-type well regions). The second doped region 115 is located between the first portion 108-1 and the second portion 108-2 of the first doped region 108, and the second doped region 115 is not in direct contact with the first doped region 108. The first well region 105 is located between the first doped region 108 and the second doped region 115. Moreover, the second doped region 115 and the third doped region 113 may have the same doping concentration, for example, about 1E13 atoms/cm² to about 3E14 atoms/cm². The second doped region 115 and the third doped region 113 may further have the same doping depth, and the bottom surfaces of both the second doped region 115 and the third doped region 113 may be at the same level in depth. In addition, the bottom surface of the second doped region 115 is lower than the bottom surface of the first doped region 108, and the bottom surface of the third doped region 113 is lower than the bottom surface of the fourth doped region 111.

Next, referring to FIG. 7, in step S109, a dielectric layer 119 and an electrically conductive structure 121 are formed on the peripheral portion of the first doped region 108, for example, the second portion 108-2 and the third portion 108-3 as shown in FIG. 1, and directly above the first isolation structure 120A by using deposition, photolithography and etching processes. In one embodiment, the composition of the dielectric layer 119 is, for example, silicon oxide, and the composition of the electrically conductive structure 121 is, for example, polysilicon. Firstly, a silicon oxide layer and a polysilicon layer may be deposited on the substrate 101 in sequence, and a patterned photoresist is formed on the polysilicon layer to be used as an etch mask. Then, the silicon oxide layer and the polysilicon layer are simultaneously etched by an etching process and using the etch mask to form the dielectric layer 119 and the electrically conductive structure 121. In some embodiments, the dielectric layer 119 and the electrically conductive structure 121 may be fabricated together with gate structures of other transistors.

Afterwards, a heavily doped region 117 such as an n-type heavily doped region (N⁺) is formed in the fourth doped region 111 by using a patterned mask such as a patterned photoresist and an ion implantation process. The heavily doped region 117 is located directly above and in direct contact with the third doped region 113. Moreover, the heavily doped region 117 is located between the first isolation structure 120A and the second isolation structure 120B. The doping concentration of the heavily doped region 117 is higher than the doping concentration of the third doped region 113. In one embodiment, the doping concentration of the heavily doped region 117 is, for example, about 5E15 atoms/cm² to about 1E16 atoms/cm².

Next, referring to FIG. 8, in step S111, an interlayer dielectric (ILD) layer 130 is blanketly deposited on the substrate 101, and multiple contact holes 131, 133 and 135 are formed in the ILD layer 130 by using a patterned mask and an etching process. The contact hole 131 exposes the second doped region 115, the contact hole 133 exposes the heavily doped region 117, and the contact hole 135 exposes the electrically conductive structure 121. Then, a metal material layer is deposited on the ILD layer 130, and the multiple contact holes 131, 133 and 135 are filled up with the metal material of the metal material layer to form multiple contact plugs 132, 134 and 136 as shown in FIG. 2. Thereafter, the metal material layer is patterned by using photolithography and etching processes to form an anode electrode 141 and a cathode electrode 143. In some embodiments, the anode electrode 141, the cathode electrode 143, and the multiple contact plugs 132, 134 and 136 may be formed of the same metal material. In other embodiments, the anode electrode 141 and the cathode electrode 143 may be formed of the same metal material, and the multiple contact plugs 132, 134 and 136 are formed of another metal material. Referring to FIG. 2, the anode electrode 141 is connected to the contact plugs 132 and 136, and the cathode electrode 143 is connected to the contact plug 134. The second doped region 115 is electrically connected to the anode electrode 141 through the contact plug 132. The electrically conductive structure 121 is electrically connected to the anode electrode 141 through the contact plug 136. The heavily doped region 117 and the third doped region 113 are electrically connected to the cathode electrode 143 through 134. Thereafter, the fabrication of the the contact plug semiconductor device 100 is completed.

According to some embodiments of the present disclosure, the second doped region such as an n-type doped region or an n-type well region with a higher doping concentration than the first well region is disposed at the anode end, thereby effectively increasing the capability of driving current of the SBD. Therefore, the forward current (IF) of the Schottky barrier diode (SBD) is increased and the breakdown voltage (BV) of the SBD is maintained. In addition, the second doped region is simultaneously formed at the anode end by using the photo-mask and the ion implantation process for forming the third doped region at the cathode end. Therefore, according to the embodiments of the present disclosure, the overall electrical performances of the semiconductor device are greatly improved without additional photo-masks and process steps.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate;
a first well region, having a first conductivity type and disposed in the substrate;
a first doped region, having a second conductivity type and disposed in the first well region, wherein the first doped region comprises a first portion and a second portion laterally separated from each other;
a second doped region, having the first conductivity type, disposed between the first portion and the second portion, and not in direct contact with the first portion and the second portion;
a third doped region, having the first conductivity type, disposed in the first well region and surrounding the first doped region and the second doped region;
an anode electrode, disposed above the substrate and electrically connected to the second doped region; and
a cathode electrode, disposed above the substrate and electrically connected to the third doped region.

2. The semiconductor device of claim 1, wherein a doping concentration of the second doped region is higher than a doping concentration of the first well region.

3. The semiconductor device of claim 1, wherein a doping concentration of the second doped region is the same as a doping concentration of the third doped region.

4. The semiconductor device of claim 1, wherein a bottom surface of the second doped region is level with a bottom surface of the third doped region.

5. The semiconductor device of claim 1, wherein when viewed from a top view, the first portion and the second portion of the first doped region and the third doped region comprise a first annular region, a second annular region and a third annular region arranged in a racetrack shape from inside to outside in sequence, respectively, and the second doped region comprises a fourth annular region and a block, wherein the fourth annular region is located between the first annular region and the second annular region, and the block is surrounded by the first annular region.

6. The semiconductor device of claim 1, wherein when viewed from a top view, the third doped region comprises a main comb-shaped region, the first doped region comprises a first sub-comb-shaped region located between a first strip portion and a second strip portion of the main comb-shaped region, and the second doped region comprises a first elongated block located between a first sub-strip portion and a second sub-strip portion of the first sub-comb-shaped region.

7. The semiconductor device of claim 6, wherein the second doped region further comprises a second elongated block located between the second sub-strip portion and a third sub-strip portion of the first sub-comb-shaped region.

8. The semiconductor device of claim 6, wherein the first doped region further comprises a second sub-comb-shaped region located between the second strip portion and a third strip portion of the main comb-shaped region.

9. The semiconductor device of claim 8, wherein the second doped region further comprises a third elongated block and a fourth elongated block, the third elongated block is located between a fourth sub-strip portion and a fifth sub-strip portion of the second sub-comb-shaped region, and the fourth elongated block is located between the fifth sub-strip portion and a sixth sub-strip portion of the second sub-comb-shaped region.

10. The semiconductor device of claim 9, wherein the first strip portion, the second strip portion and the third strip portion of the main comb-shaped region, the first sub-strip portion, the second sub-strip portion and the third sub-strip portion of the first sub-comb-shaped region, the fourth sub-strip portion, the fifth sub-strip portion and the sixth sub-strip portion of the second sub-comb-shaped region, and the first elongated block, the second elongated block, the third elongated block and the fourth elongated block of the second doped region are all laterally separated from each other and parallel to each other.

11. The semiconductor device of claim 1, wherein a bottom surface of the second doped region is lower than a bottom surface of the first doped region, and a top surface of the second doped region is level with a top surface of the first doped region.

12. The semiconductor device of claim 1, further comprising:
a fourth doped region, having the first conductivity type and disposed in the first well region, wherein the third doped region is located in the fourth doped region; and
a heavily doped region, having the first conductivity type, disposed in the fourth doped region and directly above the third doped region, wherein the cathode electrode is electrically connected to the heavily doped region.

13. The semiconductor device of claim 12, wherein a doping concentration of the third doped region is higher than a doping concentration of the fourth doped region, and a doping concentration of the heavily doped region is higher than the doping concentration of the third doped region.

14. The semiconductor device of claim 12, wherein the third doped region is in direct contact with the heavily doped region, and a bottom surface of the third doped region is lower than a bottom surface of the fourth doped region.

15. The semiconductor device of claim 12, wherein the fourth doped region is laterally separated from the first doped region, and a bottom surface of the fourth doped region is lower than a bottom surface of the first doped region.

16. The semiconductor device of claim 12, further comprising:
a first isolation structure, disposed in the first well region and between the first doped region and the fourth doped region;
an electrically conductive structure, disposed on the first doped region and laterally extending onto the first isolation structure, wherein the electrically conductive structure is electrically connected to the anode electrode; and
a dielectric layer, disposed between the electrically conductive structure and the first doped region, and between the electrically conductive structure and the first isolation structure.

17. The semiconductor device of claim 1, further comprising:
a buried layer, having the first conductivity type, disposed in the substrate, located directly below the first well region, and in direct contact with the first well region;
a second well region, having the second conductivity type, disposed in the substrate, surrounding and abutting the first well region;
a third well region, having the second conductivity type and disposed in the second well region, wherein a doping concentration of the third well region is higher than a doping concentration of the second well region; and
a second isolation structure, disposed between the first well region and the second well region.

18. The semiconductor device of claim 17, wherein a bottom surface of the second well region is level with a bottom surface of the first well region.

19. The semiconductor device of claim 1, wherein compositions of the anode electrode and the cathode electrode comprise a metal, and the semiconductor device comprises a Schottky barrier diode.

20. The semiconductor device of claim 1, wherein the substrate has the second conductivity type.
